(19) United States
(12) Patent Application Publication
(10) Pub. No.: US 2023/0201877 A1
(43) Pub. Date: Jun. 29, 2023

(54) MICRO ELECTRO MECHANICAL SYSTEMS SENSOR AND METHOD FOR MANUFACTURING THE SAME

(71) Applicant: DENSO CORPORATION, Kariya-city (JP)

(72) Inventors: Tetsuya ENOMOTO, Kariya-city (JP); Akihiko TESHIGAHARA, Kariya-city (JP); Hideo YAMADA, Kariya-city (JP); Yusuke KAWAI, Kariya-city (JP)

(21) Appl. No.: 18/170,121

(22) Filed: Feb. 16, 2023

Related U.S. Application Data
(63) Continuation of application No. PCT/JP2021/030997, filed on Aug. 24, 2021.

(30) Foreign Application Priority Data
Sep. 1, 2020 (JP) 2020-146975

(51) Int. Cl. B06B 1/06; G01S 15/04; C23C 14/34; C23C 14/06; C23C 14/02; C01B 21/06; H10N 30/853; H10N 30/076

(52) U.S. Cl. CPC B06B 1/0666; G01S 15/04; C23C 14/34; C23C 14/0641; C23C 14/02; C01B 21/0602; H10N 30/853; H10N 30/076; C01P 2006/80; C01P 2006/40

(57) ABSTRACT

A micro-electro-mechanical systems (MEMS) sensor includes a substrate, a diaphragm portion and a piezoelectric film. The diaphragm portion is located at the substrate. The piezoelectric film is located on the diaphragm portion. The piezoelectric film is made of scandium aluminum nitride. A carbon concentration of the piezoelectric film is 2.5 atomic percent or less while an oxygen concentration of the piezoelectric film is 0.35 atomic percent or less.

### CROSS REFERENCE TO RELATED APPLICATIONS

The present application is a continuation application of International Patent Application No. PCT/JP2021/030997 filed on Aug. 24, 2021, which designated the U.S. and claims the benefit of priority from Japanese Patent Application No. 2020-146975 filed on Sep. 1, 2020. The entire disclosures of all of the above applications are incorporated herein by reference.

### TECHNICAL FIELD

The present disclosure relates to a micro-electro-mechanical systems (MEMS) sensor and a method for manufacturing the MEMS sensor.

### BACKGROUND

A MEMS sensor may be an ultrasonic sensor having a piezoelectric film made of scandium aluminum nitride (ScAlN).

### SUMMARY

The present disclosure describes a MEMS sensor having a piezoelectric film made of ScAlN, and further describes a method for manufacturing the MEMS sensor.

### BRIEF DESCRIPTION OF DRAWINGS

FIG. 1 is a cross-sectional view of an ultrasonic sensor according to a first embodiment.

FIG. 2 illustrates a relationship between a carbon concentration of a piezoelectric film and a piezoelectric strain constant.

FIG. 3 illustrates a relationship between an oxygen concentration of the piezoelectric film and the piezoelectric strain constant.

FIG. 4 illustrates a relationship among the carbon concentration of the piezoelectric electric film, the oxygen concentration of the piezoelectric film and the piezoelectric strain constant.

FIG. 5 is a schematic view that illustrates a state of forming the piezoelectric film.

FIG. 6 illustrates experimental results regarding the relationship among the oxygen concentration of the piezoelectric film, a water vapor pressure inside a chamber, and the piezoelectric strain constant.

FIG. 7 illustrates the relationship among the water vapor pressure inside the chamber illustrated in FIG. 6, the oxygen concentration of the piezoelectric film and an oxygen concentration inside a target material.

FIG. 8 illustrates the oxygen concentration of the target material illustrated in FIG. 6, the piezoelectric strain constant, and the water vapor pressure inside the chamber.

FIG. 9A illustrates partial pressure in the chamber when a substrate is arranged inside the chamber without thermal treatment and sputtering is performed.

FIG. 9B illustrates the partial pressure in the chamber when a substrate is arranged inside the chamber after the thermal treatment and sputtering is performed.

### DETAILED DESCRIPTION

In a MEMS sensor, a piezoelectric film may be formed through sputtering by adopting a target material. In the MEMS sensor, a carbon concentration of the piezoelectric film may be 2.5 at % or less by adopting the target material made of scandium aluminum (ScAl) with a carbon concentration of the target material being 5 at % or less.

The inventors of the present application had been reviewing the above-mentioned MEMS sensor, and found out that the piezoelectric property of the piezoelectric film may be degraded in a case where an oxygen concentration of the piezoelectric film is relatively high.

According to a first aspect of the present disclosure, a MEMS sensor includes a substrate, a diaphragm portion and a piezoelectric film. The diaphragm portion is located at the substrate. The piezoelectric film is located on the diaphragm portion. The piezoelectric film is made of scandium aluminum nitride. A carbon concentration of the piezoelectric film is 2.5 atomic percent or less while an oxygen concentration of the piezoelectric film is 0.35 atomic percent or less.

According to the above structure, the carbon concentration of the piezoelectric film is set to be 2.5 at % or less, and the oxygen concentration of the piezoelectric film is set to be 0.35 at % or less. Therefore, it is possible to inhibit a decrease in a piezoelectric strain constant and inhibit degradation of the piezoelectric property.

According to a second aspect of the present disclosure, a method for manufacturing a MEMS sensor includes heating of a substrate, arrangement of the substrate and a target material in a chamber, and formation of a piezoelectric film through sputtering. The MEMS sensor includes the substrate, a diaphragm portion, and the piezoelectric film. The diaphragm portion is located at the substrate. The piezoelectric film is located on the diaphragm portion. The piezoelectric film is made of scandium aluminum nitride. A carbon concentration of the piezoelectric film is set to be 2.5 atomic percent or less while an oxygen concentration of the piezoelectric film is set to be 0.35 atomic percent or less. The heating of the substrate is processed before the arrangement of the substrate and the target material in the chamber.

According to the above method, when the piezoelectric film is formed, it is possible to inhibit an increase in water vapor pressure in the chamber and inhibit an increase in the oxygen concentration of the piezoelectric film. Therefore, it is possible to manufacture the MEMS sensor that inhibits degradation of the piezoelectric property.

The following describes embodiments of the present disclosure with reference to the drawings. In the following embodiments, the same or equivalent parts are denoted by the same reference numerals for description.

### First Embodiment

The following describes a first embodiment with reference to the drawings. The present embodiment describes an ultrasonic sensor as an example of MEMS sensors. The ultrasonic sensor in the present embodiment may be adapted to the surrounding of a bumper of a vehicle to form an object detector to detect an object located around the vehicle.

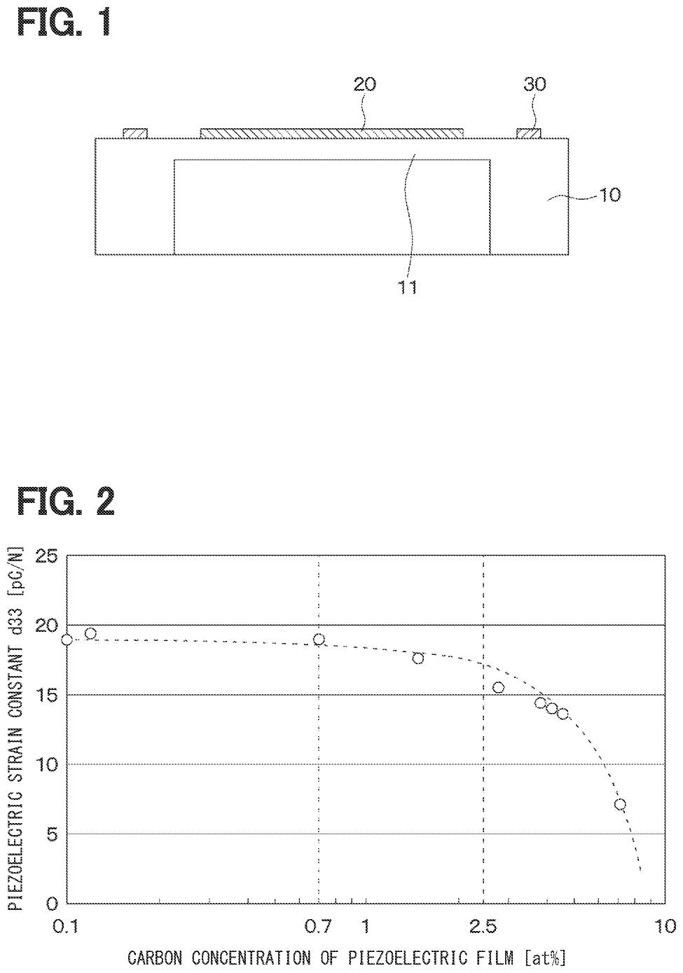

As illustrated in FIG. 1, in the ultrasonic sensor according to the present embodiment, a diaphragm portion 11 is formed at a substrate 10 made of, for example, silicon, and a piezoelectric film 20 is formed on the diaphragm portion 11.

Although it is not particularly limited, the planar shape of the diaphragm portion 11 in the present embodiment is circular. The piezoelectric film 20 is made of ScAlN, and has a smaller planar shape than the diaphragm portion 11. A structure of the piezoelectric film 20 is described hereinafter.

A pad portion 30 is formed on the substrate 10. The pad portion 30 is electrically connected to, for example, the piezoelectric film 20 through, for example, a wiring pattern (not shown). FIG. 1 illustrates the simplified relationship between the substrate 10 and the piezoelectric film 20. However, an insulating film or the like may be properly formed on the substrate 10.

The above describes the structure of the ultrasonic sensor in the present embodiment. The following describes the structure of the piezoelectric film 20 in the present embodiment.

As described above, the piezoelectric film 20 is made of ScAlN. In a case where the piezoelectric film 20 is made to satisfy ScₓAl₁₋ₓN (0<x<1), it is possible to enhance the sensitivity by increasing x as the concentration of scandium (Sc), in other words, increasing the concentration of Sc to a higher level in order to increase the piezoelectric strain constant. In a comparative example, a piezoelectric strain constant d33 suddenly increases, in a case where x is larger than or equal to 0.3. Therefore, it may be preferably to set x being larger than or equal to 0.3 for the above relation in the comparative example.

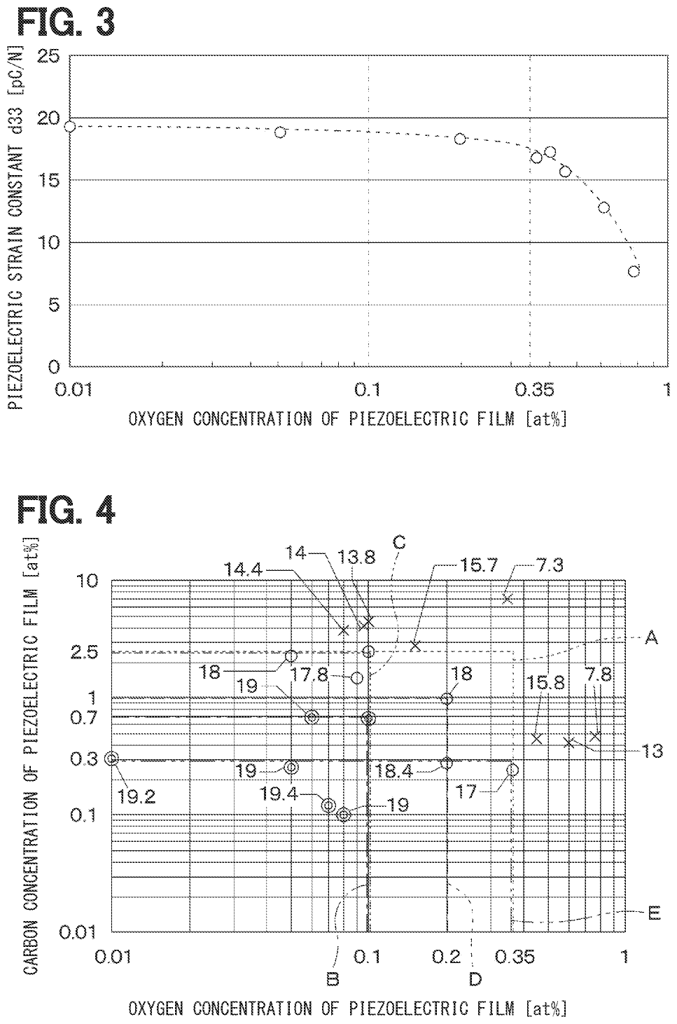

The inventors of the present application had been reviewing the relationship between the carbon concentration of the piezoelectric film 20 and the piezoelectric strain constant d33, and obtained results in FIG. 2. The inventors of the present application had been reviewing the relationship between the oxygen concentration of the piezoelectric film 20 and the piezoelectric strain constant d33, and obtained results in FIG. 3. Each of FIGS. 2 and 3 illustrates the results in a case where x is larger than or equal to 0.3 in ScₓAl₁₋ₓN (0<x<1) for the piezoelectric film 20.

As illustrated in FIG. 2, it is confirmed that the piezoelectric strain constant d33 gradually drops when the carbon concentration becomes larger than 0.7 at %; and the piezoelectric strain constant d33 suddenly drops when the carbon concentration becomes larger than 2.5 at %. As illustrated in FIG. 3, it is confirmed that the piezoelectric strain constant d33 gradually drops when the oxygen concentration becomes larger than 0.1 at %; and the piezoelectric strain constant d33 suddenly drops when the oxygen concentration becomes larger than 0.35 at %.

Therefore, in the present embodiment, the carbon concentration of the piezoelectric film 20 is set to be 2.5 at % or less, and the oxygen concentration of the piezoelectric film 20 is set to be 0.35 at % or less. According to the above structure, the carbon concentration of the piezoelectric film 20 may be set to be 2.5 at % or less, and the oxygen concentration of the piezoelectric film 20 may be set to be 0.35 at % or less. The atomic percent (at %) of the carbon concentration is the number of carbon atoms with respect to the total amount 100 at % of the number of scandium (Sc) atoms, the number of aluminum (Al) atoms and nitrogen (N) atoms. Similarly, the atomic percent (at %) of the oxygen concentration is the number of oxygen atoms with respect to the total amount 100 at % of the number of scandium (Sc) atoms, the number of aluminum (Al) atoms and nitrogen (N) atoms.

The inventors of the present application had been reviewing the relationship among the carbon concentration of the piezoelectric film 20, the oxygen concentration of the piezoelectric film 20, and the piezoelectric strain constant d33, and obtained results in FIG. 4. Each numerical value in FIG. 4 indicates the piezoelectric strain constant d33 [pC/N]. In FIG. 4, a double circle indicates that the piezoelectric strain constant is larger than or equal to 19 [pC/N]; and a circle indicates that the piezoelectric strain constant is larger than or equal to 17 [pC/N] and is smaller than 19 [pC/N]. FIG. 4 illustrates the results in a case where x is larger than or equal to 0.3 in ScₓAl₁₋ₓN (0<x<1) for the piezoelectric film 20.

17 [pC/N] of the piezoelectric strain constant d33 is a value at which the piezoelectric strain constant d33 begins to drop suddenly as viewed in FIGS. 2 and 3. 19 [pC/N] of the piezoelectric strain constant d33 is a value at which the piezoelectric strain constant d33 begins to drop gradually as viewed in FIGS. 2 and 3. Region A in FIG. 4 indicates that the carbon concentration is 2.5 at % or less and the oxygen concentration is 0.35 at % or less. Region B in FIG. 4 indicates that the carbon concentration is 0.7 at % or less and the oxygen concentration is 0.1 at % or less.

As illustrated in FIG. 4, the piezoelectric strain constant d33 is larger than or equal to 17 [PC/N] also in region C in which the carbon concentration is 2.5 at % or less and the oxygen concentration is 0.1 at % or less. The piezoelectric strain constant d33 is larger than or equal to 17 [PC/N] also in region D in which the carbon concentration is 1.0 at % or less and the oxygen concentration is 0.2 at % or less. The piezoelectric strain constant d33 is larger than or equal to 17 [PC/N] also in region E in which the carbon concentration is 0.3 at % or less and the oxygen concentration is 0.35 at % or less. In the present embodiment, the carbon concentration and the oxygen concentration may be preferable to be in the above-mentioned range. It is possible to sufficiently inhibit a decrease in the piezoelectric strain constant by setting the carbon concentration and the oxygen concentration to be in the above-mentioned range.

The following describes a method for manufacturing the piezoelectric film 20 in the ultrasonic sensor.

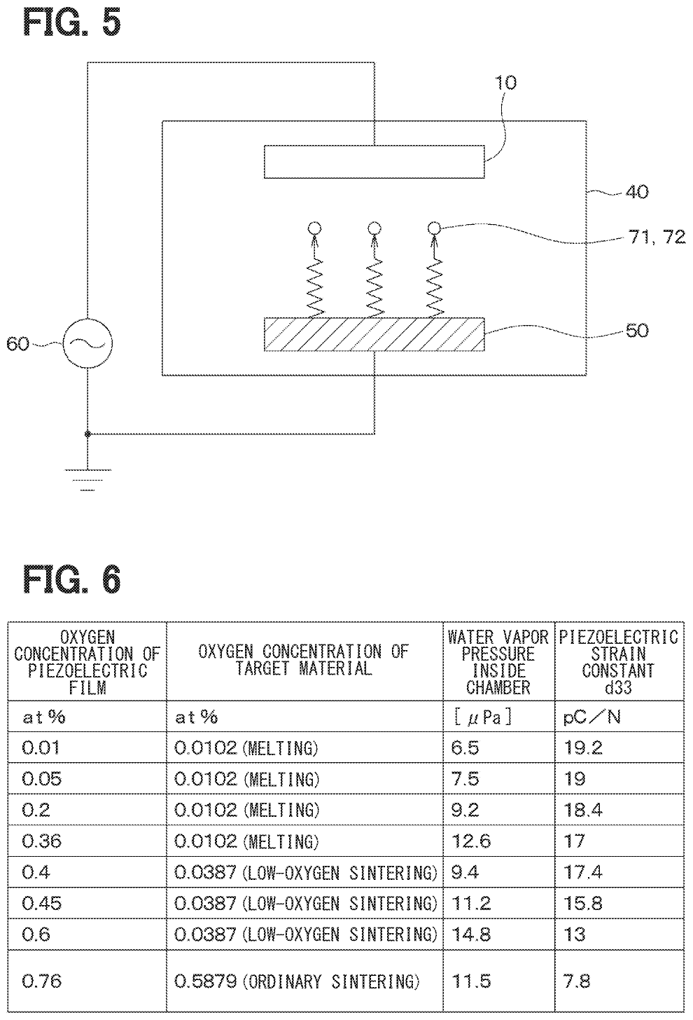

In the present embodiment, when the piezoelectric film 20 is formed, as illustrated in FIG. 5, in a chamber 40, the substrate 10 and a target material 50 are arranged to be opposite to each other, and the substrate 10 and the target material 50 are connected to a high-frequency power supply 60. The target material 50 is a scandium-aluminum alloy, and the element composition ratio of Sc to Al is about 0.45:0.55. Such a target material 50 is formed, for example, by melting, low-oxygen sintering in a state in which the surrounding oxygen concentration is reduced, or ordinary sintering in which the surrounding oxygen concentration is identical to the atmosphere.

When the piezoelectric film 20 is formed, the sputtering is performed to form the piezoelectric film 20 by attaching atoms from the target material 50 to the substrate 10. When the sputtering is performed, for example, the sputtering pressure is 0.16 pascal (Pa), the nitrogen concentration is 43 volume percent (volume %), the target power density is 10 W/cm², the substrate temperature is 300 degrees Celsius (° C.), and the sputtering time is 200 minutes. When the sputtering is performed, the pressure inside the chamber 40 is reduced to 5×10⁻⁵ Pa or less, 99.999 volume % of argon gas and 99.999 volume % of nitrogen gas are introduced into the chamber 40.

When the sputtering is performed, high-frequency plasma is formed on the surface of the target material 50 by applying a high-frequency voltage to the high-frequency power supply 60, and positive ions in the plasma collide with the target material 50 through a self-bias effect. The positive ions in the plasma are nitrogen ions and argon ions. When the positive ions collide with the target material 50, scandium atoms 71 and aluminum atoms 72 are ejected from the target material 50 and sputtered onto the substrate 10. In the present embodiment, the piezoelectric film 20 made of ScAlN is formed on the substrate 10 as described above.

The carbon concentration of the target material 50 is defined as the number of carbon atoms with respect to the total amount 100 at % of the number of the scandium atoms and the number of aluminum atoms in the target material 50. In this case, by using the target material 50 having the carbon concentration of 5 at % or less, it is possible to obtain the piezoelectric film 20 with the carbon concentration of 2.5 at % or less when the piezoelectric film 20 is formed by sputtering. As the carbon concentration of the target material 50 decreases, the carbon concentration of the piezoelectric film 20 decreases.

The inventors of the present application had been reviewing the relationship between the sputtering and the oxygen concentration of the piezoelectric film 20. The oxygen concentration of the piezoelectric film 20 depends on the pressure related to the oxygen inside the chamber 40, the oxygen concentration of the target material 50 and the moisture adhered to the substrate 10. The inventors of the present application investigated the effects of the oxygen pressure in the chamber 40, the oxygen concentration of the target material 50 and the moisture adhered to the substrate 10, and obtained the results illustrated in FIGS. 6, 7, 8, 9A and 9B.

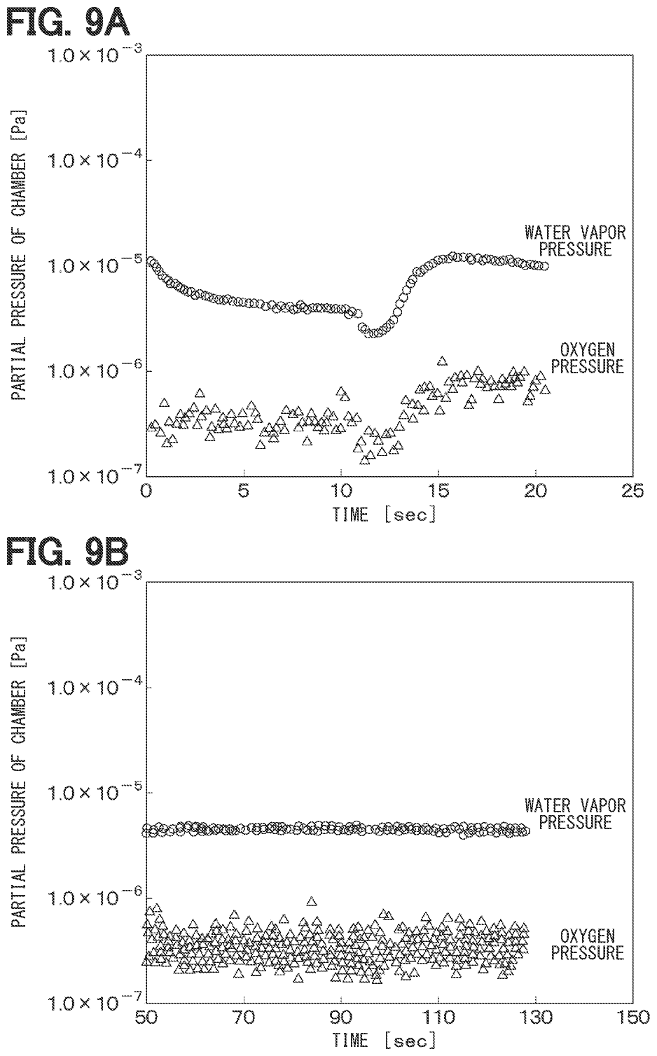

The oxygen and water vapor exist as components related to oxygen inside the chamber 40. However, the water vapor pressure is larger than the oxygen pressure by 1 order of magnitude or more inside the chamber 40. In other words, the water vapor pressure inside the chamber 40 is dominant as a component related to the oxygen inside the chamber 40. FIG. 6 illustrates the result related to the relationship between the water vapor pressure inside the chamber (hereinafter simply referred to as the water vapor pressure) and the oxygen concentration of the piezoelectric film. Also, each plotted value illustrated in FIG. 8 indicates the water vapor pressure in the chamber illustrated in FIG. 6. Each of FIGS. 6 to 8 illustrates the results when the substrate 10 is under thermal treatment as in FIG. 9B. More specifically, each of FIGS. 6 to 8 illustrates the results when the substrate 10 is heated at a higher temperature than sputtering. Atomic percent (at %) of the oxygen concentration of the target material in FIG. 6 is the number of oxygen atoms with respect to the total amount 100 at % of the number of scandium atoms and the number of aluminum atoms in the target material 50. Each of melting, low-oxygen sintering, and ordinary sintering next to the corresponding numerical values of the oxygen concentration of the target material in FIG. 6 indicates a method of manufacturing the target material 50.

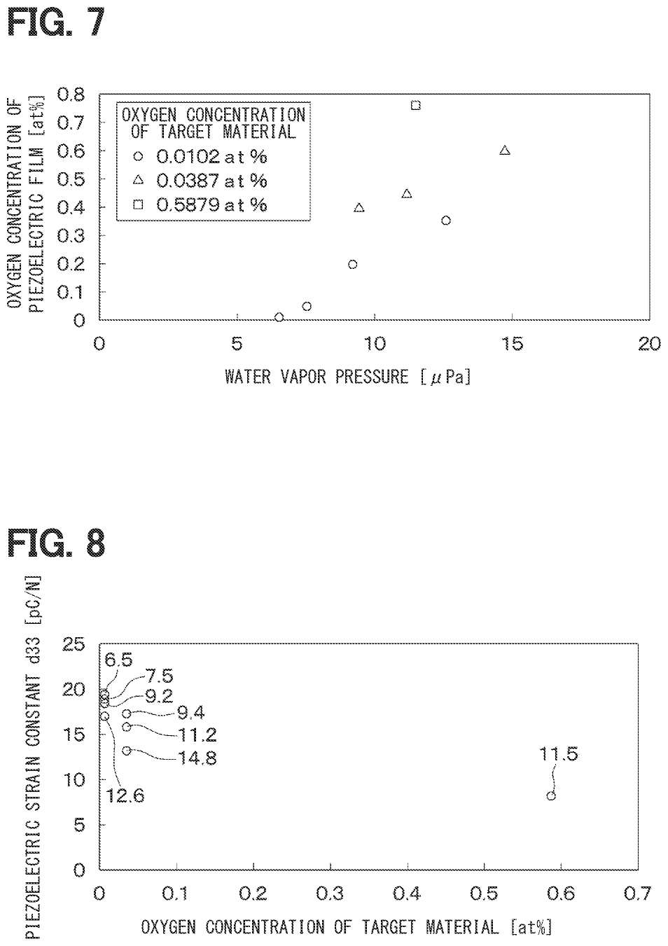

As illustrated in FIGS. 6 and 7, it is confirmed that the oxygen concentration of the piezoelectric film 20 increases as the water vapor pressure inside the chamber 40 increases. As illustrated in FIGS. 6 to 8, it is confirmed that the piezoelectric strain constant d33 decreases since the oxygen concentration of the piezoelectric film 20 increases as the oxygen concentration inside the target material 50 increases. Therefore, for forming the piezoelectric film 20 with a lower oxygen concentration, the water vapor pressure inside the chamber 40 should be lowered or the oxygen concentration in the target material 50 should be lowered.

As illustrated in FIG. 9A, in a case where the sputtering is performed in a state where the moisture is adhered to the substrate 10 without heating the substrate 10, it is confirmed that the water vapor pressure inside the chamber 40 increases since the moisture adhered to the substrate 10 evaporates. On the other hand, as illustrated in FIG. 9B, in a case where the sputtering is performed after heating the substrate 10 to remove the moisture from the substrate 10, it is confirmed that the water vapor pressure inside the chamber is substantially constant.

When the piezoelectric film 20 is formed by sputtering, it is possible to inhibit an increase in the water vapor pressure inside the chamber 40 and is possible to form the piezoelectric film 20 with a lower oxygen concentration by keeping a state in which the moisture does not adhere to the substrate 10. In this case, the substrate 10 is heated at a temperature higher than the temperature at which the sputtering is performed, so that it is possible to sufficiently inhibit the generation of the water vapor from the substrate at the time of performing the sputtering. FIG. 9B illustrates the result of adopting the substrate 10 heated at a temperature higher than a temperature at which sputtering is performed.

For example, when the oxygen concentration of the piezoelectric film 20 is set to 0.7 at % or less, the piezoelectric film 20 may be formed by adopting the heated substrate 10 by setting the oxygen concentration of the target material 50 to 0.0387 at % and setting the water vapor pressure inside the chamber 40 to 14.8 micropascals (μPa) or less. In this case, it is possible to further decrease the oxygen concentration of the piezoelectric film 20 by further decreasing the oxygen concentration of the target material 50. When the oxygen concentration of the target material 50 is desired to be further decreased, it is also possible to set the oxygen concentration of the piezoelectric film 20 to be 0.7 at % or less even if the water vapor pressure inside the chamber 40 is larger than or equal to 14.8 μPa. In other words, the water vapor pressure inside the chamber 40 and the oxygen concentration of the target material 50 may be properly modified as long as the oxygen concentration of the piezoelectric film 20 is a desirable value. By performing the thermal treatment for the substrate 10 as described above, it is possible to decrease the water vapor pressure inside the chamber 40 and it is possible to inhibit an increase in the oxygen concentration of the piezoelectric film 20.

In the present embodiment as described above, the carbon concentration of the piezoelectric film 20 is set to be 2.5 at % or less, and the oxygen concentration of the piezoelectric film 20 is set to be 0.35 at % or less. Therefore, it is possible to inhibit a decrease in the piezoelectric strain constant d33. In this case, it is possible to further inhibit a decrease in the piezoelectric strain constant d33 by setting the carbon concentration of the piezoelectric film 20 to 0.7 at % or less and setting the oxygen concentration of the piezoelectric film 20 to 0.1 at %.

It is possible to further sufficiently inhibit a decrease in the piezoelectric strain constant d33 by setting the carbon concentration of the piezoelectric film 20 to 2.5 at % or less and setting the oxygen concentration of the piezoelectric film 20 to 0.1 at %. It is also possible to further sufficiently inhibit a decrease in the piezoelectric strain constant d33 by setting the carbon concentration of the piezoelectric film 20 to 1.0 at % or less and setting the oxygen concentration of the piezoelectric film 20 to 0.2 at %. In this case, it is possible to further sufficiently inhibit a decrease in the piezoelectric strain constant d33 by setting the carbon concentration of the piezoelectric film 20 to 0.3 at % or less and setting the oxygen concentration of the piezoelectric film 20 to 0.35 at %.

When the piezoelectric film 20 is formed by sputtering, the substrate 10 processed with the thermal treatment is adopted. Therefore, when the piezoelectric film 20 is formed, it is possible to inhibit an increase in water vapor pressure in the chamber 40 and inhibit an increase in the oxygen concentration of the piezoelectric film 20. In this case, the substrate 10 is processed with the thermal treatment at a temperature higher than the temperature at which the sputtering is performed, so that it is possible to further inhibit an increase in the water vapor pressure inside the chamber 40 since the water vapor is hardly generated from the substrate 10 at the time of sputtering.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

For example, in the above first embodiment, the substrate 10 may be processed by thermal treatment at a temperature lower than the temperature at the time of sputtering. Even though the thermal treatment is performed as described above, it is possible to inhibit an increase in the water vapor pressure inside the chamber 40 at the time of sputtering, since it is possible to remove the moisture adhered to the substrate 10 through the thermal treatment. In other words, it is possible to inhibit an increase in the oxygen concentration of the piezoelectric film 20.

The MEMS sensor in the first embodiment may be applied to a sensor other than the ultrasonic sensor. For example, it is also possible to be applied to a pressure sensor having the piezoelectric film 20 on the diaphragm portion 11.

What is claimed is:

1. A micro-electro-mechanical systems (MEMS) sensor comprising:
a substrate;
a diaphragm portion located at the substrate; and
a piezoelectric film located on the diaphragm portion, wherein
the piezoelectric film is made of scandium aluminum nitride, and
a carbon concentration of the piezoelectric film is 2.5 atomic percent or less while an oxygen concentration of the piezoelectric film is 0.35 atomic percent or less.

2. The MEMS sensor according to claim 1, wherein the carbon concentration of the piezoelectric film is 2.5 atomic percent or less while the oxygen concentration of the piezoelectric film is 0.1 atomic percent or less.

3. The MEMS sensor according to claim 1, wherein the carbon concentration of the piezoelectric film is 1.0 atomic percent or less while the oxygen concentration of the piezoelectric film is 0.2 atomic percent or less.

4. The MEMS sensor according to claim 1, wherein the carbon concentration of the piezoelectric film is 0.3 atomic percent or less while the oxygen concentration of the piezoelectric film is 0.35 atomic percent or less.

5. The MEMS sensor according to claim 1, wherein the carbon concentration of the piezoelectric film is 0.7 atomic percent or less while the oxygen concentration of the piezoelectric film is 0.1 atomic percent or less.

6. A method for manufacturing a micro-electro-mechanical systems (MEMS) sensor, the method comprising:
heating a substrate;
arranging the substrate and a target material in a chamber; and
forming a piezoelectric film through sputtering, wherein
the MEMS sensor includes:
the substrate;
a diaphragm portion located at the substrate; and
the piezoelectric film located on the diaphragm portion,
the piezoelectric film is made of scandium aluminum nitride,
a carbon concentration of the piezoelectric film is set to be 2.5 atomic percent or less while an oxygen concentration of the piezoelectric film is set to be 0.35 atomic percent or less, and
the heating of the substrate is processed before the arranging of the substrate and the target material in the chamber.

7. The method according to claim 6, wherein a temperature during the heating of the substrate is higher than a temperature during the sputtering.
